(19) United States
(12) Patent Application Publication
(10) Pub. No.: US 2025/0183932 A1
(43) Pub. Date: Jun. 5, 2025

(54) RADIO FREQUENCY MODULE AND COMMUNICATION DEVICE

(71) Applicant: Murata Manufacturing Co., Ltd., Nagaokakyo-shi (JP)

(72) Inventor: Masakazu MIZOKAMI, Nagaokakyo-shi (JP)

(73) Assignee: Murata Manufacturing Co., Ltd., Nagaokakyo-shi (JP)

(21) Appl. No.: 19/043,559

(22) Filed: Feb. 3, 2025

Related U.S. Application Data
(63) Continuation of application No. PCT/JP2023/026002, filed on Jul. 14, 2023.

(30) Foreign Application Priority Data
Aug. 25, 2022 (JP) 2022-134479

(51) Int. Cl. H04B 1/38; H03F 3/24

(52) U.S. Cl. CPC H04B 1/38; H03F 3/245; H03F 2200/451

(57) ABSTRACT

A radio frequency module includes amplifiers that form an amplifier circuit of differential amplification type, a switch that has a common terminal and selection terminals, a switch that has a common terminal and selection terminals, a filter that has balanced terminals and an unbalanced terminal and that has a passband including a first band, and a filter that has balanced terminals and an unbalanced terminal and that has a passband including a second band.

### CROSS-REFERENCE TO RELATED APPLICATIONS

This is a continuation application of PCT/JP2023/026002, filed on Jul. 14, 2023, designating the United States of America, which is based on and claims priority to Japanese Patent Application No. JP 2022-134479 filed on Aug. 25, 2022. The entire contents of the above-identified applications, including the specifications, drawings and claims, are incorporated herein by reference in their entirety.

### TECHNICAL FIELD

The present disclosure relates to a radio frequency module and a communication device.

### BACKGROUND ART

Patent Document 1 discloses a power amplifier circuit of differential amplification type (radio frequency module). At the output ends of two amplifiers, a balance-unbalance transformer which converts balanced signals, which are output from the two amplifiers, to an unbalanced signal is disposed. The unbalanced terminal of the balance-unbalance transformer is connected to a filter.

### CITATION LIST

### Patent Document

Patent Document 1: Japanese Unexamined Patent Application Publication No. 2010-103851

### SUMMARY OF DISCLOSURE

### Technical Problem

In 3GPP® (3rd Generation Partnership Project), there has been a demand for a multiband-capable radio frequency module which outputs high-power transmit signals. Meeting the demand involves a radio frequency module in which, in addition to the power amplifier circuit disclosed in Patent Document 1, multiple filters and a switch for switching among the filters are disposed.

However, assuming the radio frequency module is compatible with high-power transmission, power consumption is increased, and high electric power handling capability is required for the switch and the filters. Assuming the area is increased to enhance the electric power handling capability of the switch and the filters, the transmission loss is increased.

The present disclosure is made to solve the issue, and a feature thereof is to provide a high-power radio frequency module and a high-power communication device which allow low power consumption and a reduction in size.

### Solution to Problem

To attain the feature, a radio frequency module according to an aspect of the present disclosure includes a first amplifier and a second amplifier that form an amplifier circuit of differential amplification type; a first switch that has a first common terminal, a first selection terminal, and a second selection terminal; a second switch that has a second common terminal, a third selection terminal, and a fourth selection terminal; a first filter that has a first balanced terminal, a second balanced terminal, and a first unbalanced terminal and that has a passband including a first band; and a second filter that has a third balanced terminal, a fourth balanced terminal, and a second unbalanced terminal and that has a passband including a second band. The first common terminal is connected to an output end of the first amplifier. The second common terminal is connected to an output end of the second amplifier. The first selection terminal is connected to the first balanced terminal. The second selection terminal is connected to the third balanced terminal. The third selection terminal is connected to the second balanced terminal. The fourth selection terminal is connected to the fourth balanced terminal.

### Effects of Disclosure

The present disclosure may provide a high-power radio frequency module and a high-power communication device which allow low power consumption and a reduction in size.

### BRIEF DESCRIPTION OF DRAWINGS

FIG. 1 is a diagram illustrating the circuit configuration of a radio frequency module and a communication device according to an embodiment.

FIG. 2 is a diagram illustrating exemplary connection configurations of switches and filters according to an embodiment.

FIG. 3 is a diagram illustrating an exemplary electrode configuration of a filter according to an embodiment.

FIG. 4 is a diagram for comparison between required power values of a radio frequency module according to an embodiment and those of a radio frequency module according to a comparison example.

FIG. 5 is a diagram illustrating the circuit configuration of a radio frequency module and a communication device according to a modified example.

FIG. 6 is a plan view of a radio frequency module according to an embodiment.

### DESCRIPTION OF EMBODIMENTS

Embodiments of the present disclosure will be described below in detail. The embodiments below each describe a comprehensive or specific example. Values, shapes, materials, components, the arrangement and the connection forms of components, and the like, which are described in the embodiments below, are exemplary, and are not intended to limit the present disclosure. Among components in an embodiment example and a modified example below, components that are not described in independent claims are described as optional components. The sizes or the ratios in size of the components illustrated in the drawings are not necessarily strict. In the figures, substantially the same configurations are designated with identical reference numerals. Repeated description may be avoided or simplified.

In the present disclosure, terms indicating the relationship between components, such as parallel and perpendicular, terms indicating the shapes of components, such as rectangular, and numerical ranges do not represent only strict meaning, and mean substantially equivalent ranges, for example, having errors in the order of a few percent.

In the present disclosure, “to be connected” encompasses, not only the case of direct connection using connection terminals and/or wiring conductors, but also the case of electrical connection via other circuit devices. “To be connected between A and B” may be understood to be a connection to A and B on a path connecting A to B.

In the present disclosure, a “path” may be understood to be a transmission line formed, for example, of wiring through which radio frequency signals are propagated, an electrode which is directly connected to the wiring, and a terminal connected directly to the wiring or the electrode.

In the present disclosure, “component A disposed serially to path B” may be understood to be that the signal input end and the signal output end of component A are connected either to wiring, an electrode, or a terminal included in path B.

In the component layout in the present disclosure, the state in which circuit device A (or wiring A) and circuit device B (or wiring B) are disposed adjacent to each other (or are adjacent to each other) on a module substrate may be understood to be that, in plan view of the module substrate, other circuit devices (and wiring) are not disposed between circuit device A (or wiring A) and circuit device B (or wiring B).

### Embodiment

### [1. The Circuit Configuration of a Radio Frequency Module 1 and a Communication Device 4]

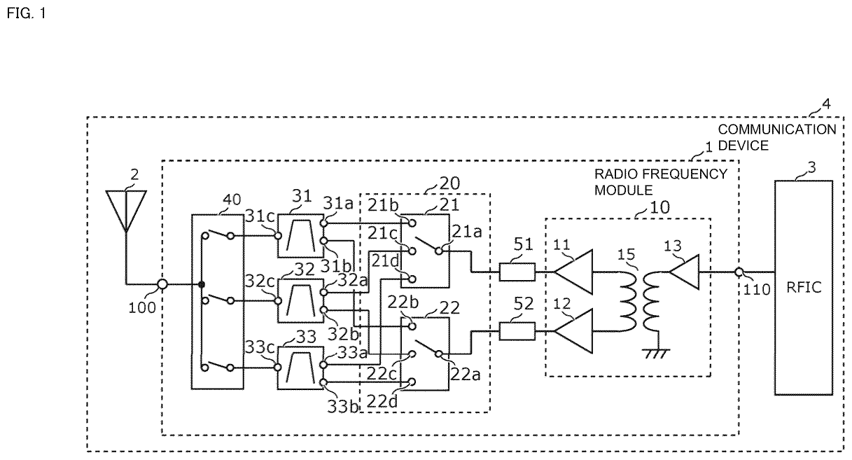

The circuit configuration of a radio frequency module 1 and a communication device 4, which includes the radio frequency module 1, according to the present embodiment will be described by referring to FIG. 1. FIG. 1 is a diagram illustrating the circuit configuration of the radio frequency module 1 and the communication device 4 according to the embodiment.

### [1.1 The Circuit Configuration of the Communication Device 4]

The communication device 4, which corresponds to a so-called user equipment (UE), is typically, for example, a cellular phone, a smartphone, or a tablet computer. Such a communication device 4 includes the radio frequency module 1, an antenna 2, and an RF signal processing circuit (RFIC: Radio Frequency Integrated Circuit) 3.

The radio frequency module 1 transmits radio frequency signals between the antenna 2 and the RFIC 3. The circuit configuration of the radio frequency module 1 will be described below.

The antenna 2 is connected to an antenna connection terminal 100 of the radio frequency module 1. The antenna 2 receives radio frequency signals from the radio frequency module 1 for output to the outside.

The RFIC 3 is an exemplary signal processing circuit which processes radio frequency signals. Specifically, the RFIC 3 performs signal processing, for example, through upconverting on a transmit signal which is input from a baseband signal processing circuit (BBIC: Baseband Integrated Circuit) which is not illustrated, and outputs a transmit signal, which is generated through the signal processing, to a transmit path of the radio frequency module 1. In addition, the RFIC 3 performs signal processing, for example, through down-converting on a receive signal, which is received through a receive path of the radio frequency module 1, and outputs a receive signal, which is generated through the signal processing, to the BBIC.

The RFIC 3 controls a switch circuit 20 and a switch 40 which are included in the radio frequency module 1. Some or all of the control functions of the RFIC 3 may be configured in the outside of the RFIC 3, and, for example, may be configured in the BBIC or the radio frequency module 1.

In the communication device 4 according to the present embodiment, the antenna 2 is not a necessary component.

### [1.2 The Circuit Configuration of the Radio Frequency Module 1]

The circuit configuration of the radio frequency module 1 will be described. As illustrated in FIG. 1, the radio frequency module 1 includes a power amplifier circuit 10, the switch circuit 20, filters 31, 32, and 33, the switch 40, matching circuits 51 and 52, a signal input terminal 110, and the antenna connection terminal 100.

The power amplifier circuit 10, which is an exemplary amplifier circuit of differential amplification type, converts an unbalanced signal, which is received from the signal input terminal 110, to two balanced signals, and amplifies the two balanced signals. The power amplifier circuit 10 includes amplifiers 11, 12, and 13 and a transformer 15.

The transformer 15, which is an exemplary transformer, has a primary coil and a secondary coil which are electromagnetically coupled to each other. The primary coil is connected, at its first end, to the signal input terminal 110 through the amplifier 13, and is grounded at its second end. The secondary coil is connected, at its first end, to the input end of the amplifier 11, and is connected, at its second end, to the input end of the amplifier 12. The transformer 15 converts an unbalanced signal, which is received at the first end of the primary coil, to two balanced signals having opposite phases, and outputs the two balanced signals from both the ends of the secondary coil.

The amplifier 11, which is an exemplary first amplifier, is connected between the transformer 15 and a switch 21 of the switch circuit 20, and is capable of amplifying balanced signals of a first band, a second band, and a third band. The amplifier 12, which is an exemplary second amplifier, is connected between the transformer 15 and a switch 22 of the switch circuit 20, and is capable of amplifying balanced signals of the first band, the second band, and the third band. The amplifiers 11 and 12 form an amplifier circuit of differential amplification type.

The amplifier 13 is connected between the signal input terminal 110 and the transformer 15, and is capable of amplifying unbalanced signals of the first band, the second band, and the third band.

Each of the amplifiers 11 to 13 has an amplifier transistor. The amplifier transistor is, for example, a bipolar transistor such as a heterojunction bipolar transistor (HBT) or a field effect transistor such as a MOSFET (Metal-Oxide-Semiconductor Field Effect Transistor). Examples of the material of the amplifier transistor include Si, GaAs, SiGe, and GaN.

The power amplifier circuit 10 does not necessarily include the amplifier 13. In this case, for example, an unbalanced signal, which is output from the RFIC 3, is input to the first end of the primary coil of the transformer 15. In addition, the power amplifier circuit 10 does not necessarily include the transformer 15 nor the amplifier 13. In this case, for example, a pair of balanced signals, which are output from the RFIC 3, are input to the amplifiers 11 and 12, respectively.

The switch circuit 20 includes the switches 21 and 22. The switch 21, which is an exemplary first switch, has a common terminal 21a (first common terminal), a selection terminal 21b (first selection terminal), a selection terminal 21c (second selection terminal), and a selection terminal 21d. The switch 21 switches among connection between the common terminal 21a and the selection terminal 21b, connection between the common terminal 21a and the selection terminal 21c, and connection between the common terminal 21a and the selection terminal 21d. The switch 21 is a SP3T (Single Pole 3 Throw) switch.

The switch 22, which is an exemplary second switch, has a common terminal 22a (second common terminal), a selection terminal 22b (third selection terminal), a selection terminal 22c (fourth selection terminal), and a selection terminal 22d. The switch 22 switches among connection between the common terminal 22a and the selection terminal 22b, connection between the common terminal 22a and the selection terminal 22c, and connection between the common terminal 22a and the selection terminal 22d. The switch 22 is an SP3T switch.

The filter 31, which is an exemplary first filter, has a passband including the first band. The filter 31 has a balanced terminal 31a (first balanced terminal), a balanced terminal 31b (second balanced terminal), and an unbalanced terminal 31c (first unbalanced terminal).

The filter 32, which is an exemplary second filter, has a passband including the second band. The filter 32 has a balanced terminal 32a (third balanced terminal), a balanced terminal 32b (fourth balanced terminal), and an unbalanced terminal 32c (second unbalanced terminal).

The filter 33 has a passband including the third band. The filter 33 has a balanced terminal 33a, a balanced terminal 33b, and an unbalanced terminal 33c.

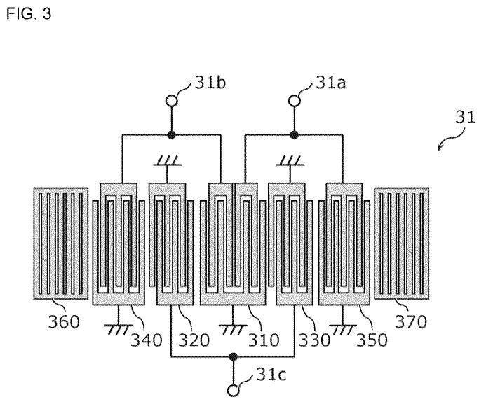

The filters 31 to 33 may be, for example, any of, but not limited to, acoustic wave filters using surface acoustic waves (SAWs), acoustic wave filters using bulk acoustic waves (BAWs), LC resonance filters, and dielectric filters. The detailed structure example of the filters 31 to 33 will be described below by using FIG. 3.

The first band, the second band, and the third band are frequency bands for a communication system constructed by using a radio access technology (RAT) predefined, for example, by a standardization organization (for example, 3GPP® or IEEE (Institute of Electrical and Electronics Engineers)). Examples of the communication system may include, but not limited to, a 5G-NR (5th Generation New Radio) system, an LTE (Long Term Evolution) system, and a WLAN (Wireless Local Area Network) system.

The matching circuit 51 is connected between the output end of the amplifier 11 and the common terminal 21a. The matching circuit 52 is connected between the output end of the amplifier 12 and the common terminal 22a. The output impedance of the power amplifier circuit 10 is set low to be able to output a high-power signal. In contrast, the input impedance of the switch circuit 20 and the filters 31 to 33, which are connected downstream, is set around the reference impedance (50Ω). Therefore, the matching circuits 51 and 52 are used to match the impedance between the amplifiers 11 and 12, and the switch circuit 20 and the filters 31 to 33.

The switch 40, which is an exemplary third switch, is connected between the antenna connection terminal 100 and the filters 31 to 33. The switch 40 switches between connection and non-connection between the antenna connection terminal 100 and the filter 31; switches between connection and non-connection between the antenna connection terminal 100 and the filter 32; and switches between connection and non-connection between the antenna connection terminal 100 and the filter 33.

The common terminal 21a is connected to the output end of the amplifier 11 through the matching circuit 51. The common terminal 22a is connected to the output end of the amplifier 12 through the matching circuit 52. The selection terminal 21b is connected to the balanced terminal 31a; the selection terminal 21c, to the balanced terminal 32a; the selection terminal 21d, to the balanced terminal 33a. The selection terminal 22b is connected to the balanced terminal 31b; the selection terminal 22c, to the balanced terminal 32b; the selection terminal 22d, to the balanced terminal 33b.

According to the configuration of the radio frequency module 1, balanced signals are transmitted through all the signal paths from the amplifiers 11 and 12 to the filters 31 to 33. Thus, compared with a circuit in which unbalanced signals are transmitted through the signal paths, the power of a signal transmitted through each signal path may be reduced, achieving low power consumption. The reduction of the signal power allows a reduction of the electric power handling capability of the switch circuit 20 and the filters 31 to 33, achieving a reduction in size of the switch circuit 20 and the filters 31 to 33. Therefore, the radio frequency module 1, which allows low power consumption and a reduction in size, may be provided.

In the radio frequency module 1 according to the present embodiment, a transformer is not connected between the output ends of the amplifiers 11 and 12 and the input ends of the filters 31 to 33.

According to this, since a transformer, which converts balanced signals to unbalanced signals, is not disposed on the signal paths from the amplifiers 11 and 12 to the filters 31 to 33, the radio frequency module 1 achieves a further reduction in size.

The radio frequency module 1 according to the present embodiment does not necessarily include the matching circuits 51 and 52 and the switch 40. In addition, any configuration may be employed as long as the number of filters is two or more. Assuming filters, whose number is n, are disposed, each of the switches 21 and 22 is an SPnT switch.

In the case where the radio frequency module 1 amplifies a signal of the first band for transmission, the common terminal 21a is connected to the selection terminal 21b, and the common terminal 22a is connected to the selection terminal 22b. In the case where the radio frequency module 1 amplifies a signal of the second band for transmission, the common terminal 21a is connected to the selection terminal 21c, and the common terminal 22a is connected to the selection terminal 22c. In the case where the radio frequency module 1 amplifies a signal of the third band for transmission, the common terminal 21a is connected to the selection terminal 21d, and the common terminal 22a is connected to the selection terminal 22d.

According to this, in the case of transmission of a signal of the first band, the first-band signal passes through the filter 31 due to the switching of the switch circuit 20. In the case of transmission of a signal of the second band, the second-band signal passes through the filter 32 due to the switching of the switch circuit 20. In the case of transmission of a signal of the third band, the third-band signal passes through the filter 33 due to the switching of the switch circuit 20.

### [1.3 The Configuration of the Switch Circuit 20]

In the switch 21, one or more semiconductor devices are serially connected between the common terminal 21a and each of the selection terminal 21b and the selection terminal 21c, and the selection terminal 21d. In the switch 22, one or more semiconductor devices are serially connected between the common terminal 22a and each of the selection terminal 22b, the selection terminal 22c, and the selection terminal 22d. Each of the one or more semiconductor devices is, for example, a FET (Field Effect Transistor) having a source electrode, a drain electrode, and a gate electrode. Each of the one or more semiconductor devices may be a bipolar transistor or a diode.

The number of serial connections of the one or more semiconductor devices is defined as the number of stacks. At that time, the number of stacks of the one or more semiconductor devices serially connected between the common terminal 21a and the selection terminal 21b is equal to that between the common terminal 22a and the selection terminal 22b. The number of stacks of the one or more semiconductor devices serially connected between the common terminal 21a and the selection terminal 21c is equal to that between the common terminal 22a and the selection terminal 22c. The number of stacks of the one or more semiconductor devices serially connected between the common terminal 21a and the selection terminal 21d is equal to that between the common terminal 22a and the selection terminal 22d.

According to this, the on-resistance of the path connecting the common terminal 21a to the selection terminal 21b is equal to that of the path connecting the common terminal 22a to the selection terminal 22b. In addition, a balanced signal flowing through the path connecting the common terminal 21a to the selection terminal 21b and a balanced signal flowing through the path connecting the common terminal 22a to the selection terminal 22b are received at the balanced terminals 31a and 31b, respectively, of the filter 31 at the same time. This enables the degree of balance between a pair of balanced signals passing through the filter 31 to be enhanced.

The on-resistance of the path connecting the common terminal 21a to the selection terminal 21c is equal to that of the path connecting the common terminal 22a to the selection terminal 22c. In addition, a balanced signal flowing through the path connecting the common terminal 21a to the selection terminal 21c and a balanced signal flowing through the path connecting the common terminal 22a to the selection terminal 22c are received at the balanced terminals 32a and 32b, respectively, of the filter 32 at the same time. This enables the degree of balance between a pair of balanced signals passing through the filter 32 to be enhanced.

The on-resistance of the path connecting the common terminal 21a to the selection terminal 21d is equal to that of the path connecting the common terminal 22a to the selection terminal 22d. In addition, a balanced signal flowing through the path connecting the common terminal 21a to the selection terminal 21d and a balanced signal flowing through the path connecting the common terminal 22a to the selection terminal 22d are received at the balanced terminals 33a and 33b, respectively, of the filter 33 at the same time. This enables the degree of balance between a pair of balanced signals passing through the filter 33 to be enhanced.

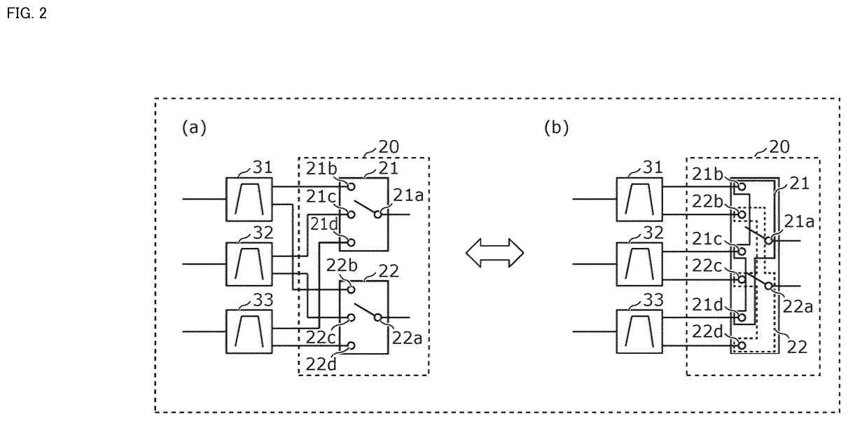

In the switch circuit 20, the switches 21 and 22 are not necessarily disposed separately, and may be integrated with each other. FIG. 2 is a diagram illustrating exemplary connection configurations of the switch circuit 20 and the filters 31 to 33 according to the embodiment.

In the configuration example illustrated in FIG. 2(a), the switches 21 and 22, each of which is an SP3T switch, are (separately) disposed so as to be spaced apart from each other. Therefore, some of wiring lines which connect the switches 21 and 22 to the filters 31 to 33 cross one another.

In contrast, in the configuration example illustrated in FIG. 2(b), the switch circuit 20 has a single DP6T (Double Pole 6 Throw) switch. That is, the switches 21 and 22 are integrated with each other, and the selection terminals 21b, 21c, and 21d and the selection terminals 22b, 22c, and 22d are disposed alternately. This optimal arrangement of the selection terminals eliminates the crossing of wiring lines connecting the switches 21 and 22 to the filters 31 to 33. Thus, compared with the configuration example in FIG. 2(a), the configuration example in FIG. 2(b) enables the degree of balance between a pair of balanced signals, which are input to the filters 31 to 33, to be further enhanced.

In FIG. 2(b), in the switch circuit 20, a part including the common terminal 21a and the selection terminals 21b, 21c, and 21d is defined as the switch 21; a part including the common terminal 22a and the selection terminals 22b, 22c, and 22d is defined as the switch 22.

### [1.4 The Configuration of the Filters 31 to 33]

The structure of the filters 31 to 33 will be described. Each of the filters 31 to 33 is a balanced filter having two balanced terminals and a single unbalanced terminal.

FIG. 3 is a diagram illustrating an exemplary electrode configuration of the filter 31 according to the embodiment. As illustrated in FIG. 3, the filter 31 is a surface acoustic wave filter of longitudinally-coupled type, for example, which has a substrate (not illustrated) having piezoelectricity, IDT (InterDigital Transducer) electrodes 310, 320, 330, 340, and 350 formed on the substrate, and reflecting electrodes 360 and 370. Each of the IDT electrodes 310 to 350 is formed by a pair of comb-like electrodes. Each comb-like electrode includes multiple electrode fingers disposed parallel to each other, and a busbar electrode which connects first ends of the electrode fingers to each other. A pair of comb-like electrodes are formed so that the electrode fingers of the two comb-like electrodes are interdigitated to each other. In the IDT electrode 310, one of the pair of comb-like electrodes is divided into two busbar electrodes for connection. The IDT electrodes 310 to 350 are disposed adjacent to each other in the order of the IDT electrodes 340, 320, 310, 330, and 350 in the direction perpendicular to the direction in which the electrode fingers extend. The reflecting electrodes 360 and 370 are disposed on both the ends of the IDT electrodes 310 to 350 so that the IDT electrodes 310 to 350 are interposed in between.

The balanced terminal 31a is connected to a first one of the pair of comb-like electrodes of the IDT electrode 350 and to the right busbar electrode of a first one of the pair of comb-like electrodes of the IDT electrode 310. The balanced terminal 31b is connected to a first one of the pair of comb-like electrodes of the IDT electrode 340 and to the left electrode of the first one of the pair of comb-like electrodes of the IDT electrode 310. The unbalanced terminal 31c is connected to a first one of the pair of comb-like electrodes of the IDT electrode 320 and to a first one of the pair of comb-like electrodes of the IDT electrode 330. A second one of the pair of comb-like electrodes of the IDT electrode 310, a second one of the pair of comb-like electrodes of the IDT electrode 320, a second one of the pair of comb-like electrodes of the IDT electrode 330, a second one of the pair of comb-like electrodes of the IDT electrode 340, and a second one of the pair of comb-like electrodes of the IDT electrode 350 are grounded.

According to the electrode configuration, the filter 31 is capable of converting a pair of balanced signals, which are received from the balanced terminals 31a and 31b, to an unbalanced signal by using the five IDT electrodes for output from the unbalanced terminal 31c. The filter 31 is capable of converting an unbalanced signal, which is received from the unbalanced terminal 31c, to a pair of balanced signals by using the five IDT electrodes for output from the balanced terminals 31a and 31b. By using the five IDT electrodes, the filter 31 has both a function of filtering received radio frequency signals and a function of balanced-unbalanced conversion. Therefore, arrangement of a balanced filter such as the filter 31 in the radio frequency module 1 eliminates necessity of disposing another balanced-unbalanced conversion device such as a transformer.

The balanced filter using an acoustic wave resonator of longitudinally-coupled type is not limited to having the electrode configuration illustrated in FIG. 3. Any configuration may be employed as long as the balanced filter using an acoustic wave resonator of longitudinally-coupled type has at least three IDT electrodes arranged in the propagation direction of acoustic waves, and has a configuration in which an IDT electrode disposed at the center is connected to the unbalanced terminal and in which the IDT electrodes disposed on the ends are connected to the respective balanced terminals.

The balanced filter may be formed by using a surface acoustic wave resonator of ladder type or a bulk-acoustic-wave resonator.

The filters 32 and 33 have substantially the same electrode configuration as that of the filter 31 illustrated in FIG. 3.

### [1.5 The Power Transitions at Nodes in the Radio Frequency Module]

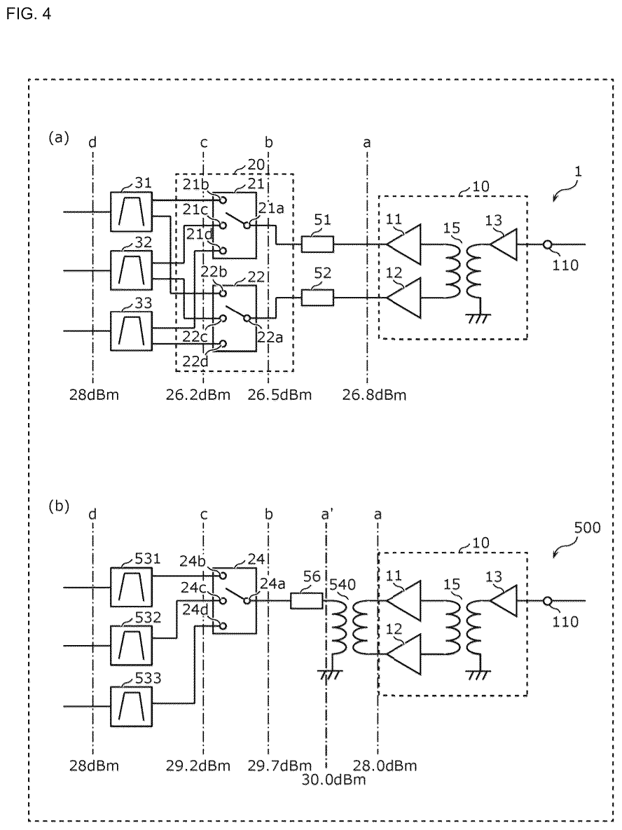

FIG. 4 is a diagram for comparison between required power values at nodes of the radio frequency module according to the embodiment and those according to a comparison example. FIG. 4(a) illustrates required power values at node a (the output ends of the power amplifier circuit 10), node b (the input ends of the switch circuit 20), node c (the output ends of the switch circuit 20), and node d (the output ends of the filters 31 to 33) in the radio frequency module 1 according to the embodiment. FIG. 4(b) illustrates required power values at node a (the output ends of the power amplifier circuit 10), node a′ (the output end of a transformer 540), node b (the input end of a switch 24), node c (the output ends of the switch 24), and node d (the output ends of filters 531 to 533) in a radio frequency module 500 according to the comparison example.

The configuration of the radio frequency module 500 according to the comparison example will be described. As illustrated in FIG. 4(b), the radio frequency module 500 according to the comparison example includes the power amplifier circuit 10, the transformer 540, the switch 24, the filters 531, 532, and 533, a matching circuit 56, and the signal input terminal 110. The radio frequency module 500 further includes the antenna connection terminal 100 and the switch 40 (not illustrated). The radio frequency module 500 according to the comparison example is different from the radio frequency module 1 according to the embodiment in the configuration of a circuit connected to the output ends of the power amplifier circuit 10. The configuration of the power amplifier circuit 10 in the radio frequency module 500 will not be described below.

The transformer 540 has a primary coil and a secondary coil which are electromagnetically coupled to each other. The primary coil is connected, at its first end, to the output end of the amplifier 11, and is connected, at its second end, to the output end of the amplifier 12. The secondary coil is connected, at its first end, to the switch 24 through the matching circuit 56, and is grounded at its second end. The transformer 540 converts a pair of balanced signals, which are received at both the ends of the primary coil, to an unbalanced signal for output from the first end of the secondary coil.

The switch 24 has a common terminal 24a and selection terminals 24b, 24c, and 24d. The switch 24 switches among connection between the common terminal 24a and the selection terminal 24b, connection between the common terminal 24a and the selection terminal 24c, and connection between the common terminal 24a and the selection terminal 24d. The switch 24 is an SP3T switch.

The filter 531, which has a passband including the first band, has two unbalanced terminals. The filter 532, which has a passband including the second band, has two unbalanced terminals. The filter 533, which has a passband including the third band, has two unbalanced terminals. Each of the filters 531 to 533 filters an input unbalanced signal with the frequency band of the corresponding band for output as an unbalanced signal.

The matching circuit 56 is connected between the output end of the transformer 540 and the common terminal 24a.

The common terminal 24a is connected to the first end of the secondary coil of the transformer 540 through the matching circuit 56. The selection terminal 24b is connected to the unbalanced terminal of the filter 531; the selection terminal 24c, to the unbalanced terminal of the filter 532; the selection terminal 24d, to the unbalanced terminal of the filter 533.

Through the configuration, the radio frequency module 500 has a circuit configuration in which a single unbalanced signal is transmitted through the paths from the input end of the matching circuit 56 to the output ends of the filters 531 to 533.

The power transitions in the radio frequency module 1 illustrated in FIG. 4(a) will be described. It is assumed that a power value of 28 dBm is required at the output ends of the filters 31 to 33 (node d). Each of the filters 31 to 33 combines a pair of balanced signals with each other for conversion into a single unbalanced signal. Thus, the power coupling gain at an unbalanced terminal with respect to each balanced terminal is 3 dB. In contrast, assume that the insertion loss of each of the filters 31 to 33 is 1.2 dB. A power value of 26.2 dBm (28 dBm−3 dB+1.2 dB) is required at each balanced terminal of the filters 31 to 33 (node c). Assume that the insertion loss between a common terminal and a selection terminal in the switches 21 and 22 is 0.3 dB. A power value of 26.5 dBm (26.2 dBm+0.3 dB) is required at each of the common terminals 21a and 22a (node b). Assume that the matching loss of each of the matching circuits 51 and 52 is 0.3 dB. A power value of 26.8 dBm (26.5 dBm+0.3 dB) is required at each of the output ends of the amplifiers 11 and 12 (node a).

The power transitions in the radio frequency module 500 illustrated in FIG. 4(b) will be described. It is assumed that a power value of 28 dBm is required at the output ends of the filters 531 to 533 (node d). Each of the filters 531 to 533 converts a single unbalanced signal to a single unbalanced signal. Thus, the power coupling gain at a first unbalanced terminal with respect to a second unbalanced terminal is 0 dB. In contrast, assume that the insertion loss of each of the filters 531 to 533 is 1.2 dB. A power value of 29.2 dBm (28 dBm+1.2 dB) is required at each unbalanced terminal on the input side of the filters 531 to 533 (node c). Assume that the insertion loss between a common terminal and a selection terminal in the switch 24 is 0.5 dB. A power value of 29.7 dBm (29.2 dBm+0.5 dB) is required at the common terminal 24a (node b). Assume that the matching loss of the matching circuit 56 is 0.3 dB. A power value of 30.0 dBm (29.7 dBm+0.3 dB) is required at the output end of the transformer 540 (node a′). The transformer 540 combines a pair of balanced signals with each other for conversion into a single unbalanced signal. Thus, the power coupling gain at the first end of the secondary coil with respect to each terminal of the primary coil is 3 dB. In contrast, assume that the coupling loss between the primary coil and the secondary coil of the transformer 540 is 1.0 dB. A power value of 28.0 dBm (30.0 dBm−3 dB+1.0 dB) is required at each of the output ends of the amplifiers 11 and 12 (node a).

The insertion loss (0.3 dB) of the switches 21 and 22 in the radio frequency module 1 according to the embodiment is smaller than the insertion loss (0.5 dB) of the switch 24 in the radio frequency module 500 according to the comparison example. This is because a reduction of the electric power handling capability decreases the number of stacks of the one or more semiconductor devices serially connected between a common terminal and a selection terminal.

Assuming the required power values at the nodes in the radio frequency module 1 according to the embodiment are compared with those in the radio frequency module 500 according to the comparison example, it is found that the radio frequency module 1 has a lower power value by 3.0 dB at node c; has a lower power value by 3.2 dB at node b; has a lower power value by 1.2 dB at node a. That is, in the radio frequency module 1 according to the embodiment, compared with the radio frequency module 500 according to the comparison example, the input power of the filters 31 to 33 is lower by 3.0 dB; the input power of the switches 21 and 22 is lower by 3.2 dB; the output power of the amplifiers 11 and 12 is lower by 1.2 dB.

The radio frequency module 1 according to the embodiment may reduce the power for the filters 31 to 33 and the switch circuit 20 by half, achieving a reduction of the transmission loss and a reduction in size of the filters 31 to 33.

In addition, no transformer is necessarily disposed on the output side of the power amplifier circuit 10, achieving a reduction of the transmission loss of the radio frequency module 1. This improves the power efficiency of the radio frequency module 1.

Since the output power of the power amplifier circuit 10 is reduced, the impedance required at the output ends of the power amplifier circuit 10 may be increased, achieving further improvement of the power efficiency.

### [1.6 The Circuit Configuration of a Radio Frequency Module 1A According to a Modified Example]

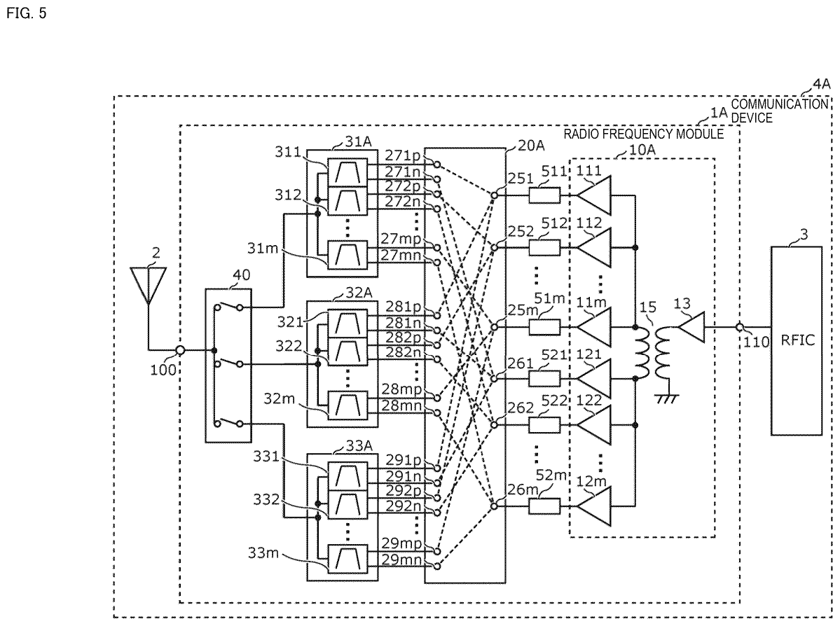

FIG. 5 is a diagram illustrating the circuit configuration of a radio frequency module 1A and a communication device 4A according to a modified example. The communication device 4A according to the present modified example includes the radio frequency module 1A, the antenna 2, and the RFIC 3. The communication device 4A according to the present modified example is different from the communication device 4 according to the embodiment in the circuit configuration of the radio frequency module 1A. Accordingly, the circuit configuration of the radio frequency module 1A according to the present modified example will be described below.

As illustrated in FIG. 5, the radio frequency module 1A includes a power amplifier circuit 10A, a switch circuit 20A, filter circuits 31A, 32A, and 33A, the switch 40, matching circuits 511, 512, 51m, 521, 522, and 52m, the signal input terminal 110, and the antenna connection terminal 100. The radio frequency module 1A according to the present modified example is different from the radio frequency module 1 according to the embodiment, which has the circuit configuration in which a pair of balanced signals are transmitted, in a circuit configuration in which m pairs of balanced signals (m is an integer of two or more) are transmitted. The radio frequency module 1A according to the present modified example will be described below by skipping description about the same configurations as those of the radio frequency module 1 according to the embodiment and by focusing on different configurations.

The power amplifier circuit 10A, which is an exemplary amplifier circuit of differential amplification type, converts an unbalanced signal, which is received from the signal input terminal 110, to m pairs of balanced signals, and amplifies the m pairs of balanced signals. The power amplifier circuit 10A includes amplifiers 111, 112, and 11m, amplifiers 121, 122, and 12m, the amplifier 13, and the transformer 15.

The transformer 15, which is an exemplary transformer, has a primary coil and a secondary coil which are electromagnetically coupled to each other. The primary coil is connected, at its first end, to the signal input terminal 110 through the amplifier 13, and is grounded at its second end. The secondary coil is connected, at its first end, to the input ends of the amplifiers 111, 112, and 11m, and is connected, at its second end, to the input ends of the amplifiers 121, 122, and 12m. The transformer 15 converts an unbalanced signal, which is received at the first end of the primary coil, to two balanced signals, having opposite phases, for output from both the ends of the secondary coil.

The amplifiers 111, 112, and 11m, which are exemplary first amplifiers, are connected between the transformer 15 and the switch circuit 20A, and are capable of amplifying balanced signals of the first band, the second band, and the third band. An expression, “amplifiers 111, 112, and 11m”, indicates first amplifiers whose number is equal to m.

The amplifiers 121, 122, and 12m, which are exemplary second amplifiers, are connected between the transformer 15 and the switch circuit 20A, and are capable of amplifying balanced signals of the first band, the second band, and the third band. An expression, “amplifiers 121, 122, and 12m”, indicates second amplifiers whose number is equal to m. The amplifiers 111, 112, and 11m and the amplifiers 121, 122, and 12m form an amplifier circuit of differential amplification type.

The switch circuit 20A includes first switches, whose number is equal to m, and second switches, whose number is equal to m.

A first one of the m first switches has a common terminal 251 (first common terminal), a selection terminal 271p (first selection terminal), a selection terminal 281p (second selection terminal), and a selection terminal 291p. A second one of the m first switches has a common terminal 252 (first common terminal), a selection terminal 272p (first selection terminal), a selection terminal 282p (second selection terminal), and a selection terminal 292p. A m-th one of the m first switches has a common terminal 25m (first common terminal), a selection terminal 27mp (first selection terminal), a selection terminal 28mp (second selection terminal), and a selection terminal 29mp. Each of the m first switches performs switching the connection between its first common terminal and any of its three selection terminals.

A first one of the m second switches has a common terminal 261 (second common terminal), a selection terminal 271n (third selection terminal), a selection terminal 281n (fourth selection terminal), and a selection terminal 291n. A second one of the m second switches has a common terminal 262 (second common terminal), a selection terminal 272n (third selection terminal), a selection terminal 282n (fourth selection terminal), and a selection terminal 292n. A m-th of the m second switches has a common terminal 26m (second common terminal), a selection terminal 27mn (third selection terminal), a selection terminal 28mn (fourth selection terminal), and a selection terminal 29mn. Each of the m second switches performs switching the connection between its second common terminal and any of its three selection terminals.

Each of the m first switches and the m second switches is an SP3T switch.

The filter circuit 31A has filters 311, 312, and 31m, and has first filters whose number is equal to m. Each of the filters 311, 312, and 31m, which is an exemplary first filter, has a passband including the first band. Each of the filters 311, 312, and 31m has two balanced terminals (first and second balanced terminals) and an unbalanced terminal (first unbalanced terminal). An expression, “filters 311, 312, and 31m”, indicates the m first filters.

The filter circuit 32A has filters 321, 322, and 32m, and has second filters whose number is equal to m. Each of the filters 321, 322, and 32m, which is an exemplary second filter, has a passband including the second band. Each of the filters 321, 322, and 32m has two balanced terminals (third and fourth balanced terminals) and an unbalanced terminal (second unbalanced terminal). An expression, “filters 321, 322, and 32m”, indicates the m second filters.

The filter circuit 33A has filters 331, 332, and 33m. Each of the filters 331, 332, and 33m has a passband including the third band. Each of the filters 331, 332, and 33m has two balanced terminals and an unbalanced terminal.

The matching circuit 511 is connected between the output end of the amplifier 111 and the common terminal 251. The matching circuit 512 is connected between the output end of the amplifier 112 and the common terminal 252. The matching circuit 51m is connected between the output end of the amplifier 11m and the common terminal 25m. The matching circuit 521 is connected between the output end of the amplifier 121 and the common terminal 261. The matching circuit 522 is connected between the output end of the amplifier 122 and the common terminal 262. The matching circuit 52m is connected between the output end of the amplifier 12m and the common terminal 26m.

The common terminal 251 (first common terminal) is connected to the output end of the amplifier 111 (first amplifier) through the matching circuit 511; the common terminal 252 (first common terminal), to the output end of the amplifier 112 (first amplifier) through the matching circuit 512; the common terminal 25m, to the output end of the amplifier 11m through the matching circuit 51m. The common terminal 261 (second common terminal) is connected to the output end of the amplifier 121 (second amplifier) through the matching circuit 521; the common terminal 262 (second common terminal), to the output end of the amplifier 122 (second amplifier) through the matching circuit 522; the common terminal 26m, to the output end of the amplifier 12m through the matching circuit 52m.

The selection terminal 271p (first selection terminal) is connected to one (first balanced terminal) of the two balanced terminals of the filter 311 (first filter); the selection terminal 281p (second selection terminal), to one (third balanced terminal) of the two balanced terminals of the filter 321 (second filter); the selection terminal 291p, to one of the two balanced terminals of the filter 331.

The selection terminal 271n (third selection terminal) is connected to the other (second balanced terminal) of the two balanced terminals of the filter 311 (first filter); the selection terminal 281n (fourth selection terminal), to the other (fourth balanced terminal) of the two balanced terminals of the filter 321 (second filter); the selection terminal 291n, to the other of the two balanced terminals of the filter 331.

The selection terminal 272p (first selection terminal) is connected to one (first balanced terminal) of the two balanced terminals of the filter 312 (first filter); the selection terminal 282p (second selection terminal), to one (third balanced terminal) of the two balanced terminals of the filter 322 (second filter); the selection terminal 292p, to one of the two balanced terminals of the filter 332.

The selection terminal 272n (third selection terminal) is connected to the other (second balanced terminal) of the two balanced terminals of the filter 312 (first filter); the selection terminal 282n (fourth selection terminal), to the other (fourth balanced terminal) of the two balanced terminals of the filter 322 (second filter); the selection terminal 292n, to the other of the two balanced terminals of the filter 332.

The selection terminal 27mp (first selection terminal) is connected to one (first balanced terminal) of the two balanced terminals of the filter 31m (first filter); the selection terminal 28mp (second selection terminal), to one (third balanced terminal) of the two balanced terminals of the filter 32m (second filter); the selection terminal 29mp, to one of the two balanced terminals of the filter 33m.

The selection terminal 27mn (third selection terminal) is connected to the other (second balanced terminal) of the two balanced terminals of the filter 31m (first filter); the selection terminal 28mn (fourth selection terminal), to the other (fourth balanced terminal) of the two balanced terminals of the filter 32m (second filter); the selection terminal 29mn, to the other of the two balanced terminals of the filter 33m.

The filters 311, 312, and 31m are connected to each other at their respective unbalanced terminals (first unbalanced terminals). The filters 321, 322, and 32m are connected to each other at their respective unbalanced terminals (second unbalanced terminals). The filters 331, 332, and 33m are connected to each other at their respective unbalanced terminals.

According to the configuration of the radio frequency module 1A, balanced signals are transmitted through all the signal paths from the output ends of the power amplifier circuit 10A to the filter circuits 31A to 33A. Thus, compared with a circuit in which unbalanced signals are transmitted through the signal paths, the power of a signal transmitted through each signal path may be reduced, achieving low power consumption. The reduction of the signal power allows a reduction of the electric power handling capability of the switch circuit 20A and the filter circuits 31A to 33A, achieving a reduction in size of the switch circuit 20A and the filter circuits 31A to 33A. Therefore, the radio frequency module 1A, which allows low power consumption and a reduction in size, may be provided.

In the configuration described above, the output power of each of the filter circuits 31A, 32A, and 33A is represented by P_{FIL} (dBm). Since, in the filter circuit 31A, the power of the m filters including the filters 311, 312, and 31m is combined, the power coupling gain of the filter circuit 31A is m×3 (dB). Similarly, the power coupling gain of each of the filter circuits 32A and 33A is m×3 (dB). The insertion loss of each filter is represented by IL_{FIL} (dB). The insertion loss between a single common terminal and a single selection terminal in the switch circuit 20A is represented by IL_{SW}. The matching loss of each matching circuit is represented by IL_{MN}. In this case, the power value P_{FIL}_I at the input end of each of the filter circuits 31A to 33A, the power value P_{SW}_I at the input end of the switch circuit 20A, and the power value P_{PA}_O at the output end of each amplifier included in the power amplifier circuit 10A are expressed in Expressions 1 to 3.

P_{FIL}_I=P_{FIL}−(m×3)+IL_{FIL} (Expression 1)

P_{SW}_I=P_{FIL}−(m×3)+IL_{FIL}+IL_{SW} (Expression 2)

P_{PA}_O=P_{FIL}−(m×3)+IL_{FIL}+IL_{SW}+IL_{MN} (Expression 3)

In Expressions 1 to 3, the radio frequency module 1 according to the embodiment corresponds to the case where m=1. Thus, in the radio frequency module 1A according to the present modified example, the number of pairs of differential amplifiers is set to m. Thus, compared with the radio frequency module 1 according to the embodiment, the power value required at each node may be reduced by 3×(m−1) (dB). That is, an increasing number of pairs of differential amplifiers may reduce the power for the filter circuits and the switch circuit, allowing application to a system which requires higher power.

### [1.7 The Mounting Configuration of the Radio Frequency Module 1]

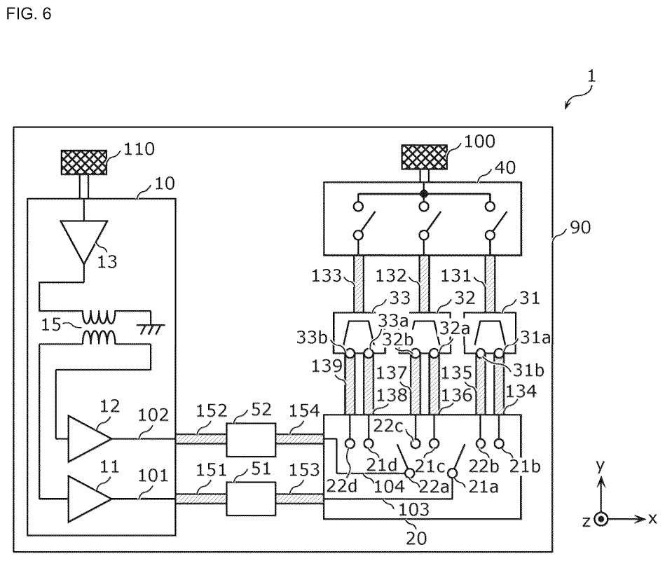

FIG. 6 is a plan view of the radio frequency module 1 according to the embodiment. FIG. 6 illustrates the layout of circuit components assuming a principal surface of a module substrate 90 is seen through from the z-axis positive direction side. In FIG. 6, a part of the module substrate 90 and some of the wiring lines connecting the circuit components are not illustrated. The radio frequency module 1 further has the module substrate 90 in addition to the circuit configuration illustrated in FIG. 1.

The module substrate 90 is a substrate which has a first principal surface and a second principal surface which are opposite each other and on or in which the circuit components included in the radio frequency module 1 are mounted. The module substrate 90 is, for example, a low temperature co-fired ceramics (LTCC) substrate, a high temperature co-fired ceramics (HTCC) substrate, a component-embedded board, a substrate having a redistribution layer (RDL), or a printed board, which has a layered structure of multiple dielectric layers.

On the first principal surface of the module substrate 90, the power amplifier circuit 10, the switch circuit 20, the switch 40, the matching circuits 51 and 52, the filters 31, 32, and 33, the antenna connection terminal 100, and the signal input terminal 110 are disposed. At least one of the circuit components may be disposed on the second principal surface of the module substrate 90 or in the module substrate 90.

The amplifiers 11 and 12 may be included in a first semiconductor IC. The transformer 15 may be formed also in the first semiconductor IC. This achieves a reduction in size of the radio frequency module 1.

The switch circuit 20 may be included in a second semiconductor IC.

The first semiconductor IC and the second semiconductor IC may be formed, for example, by using CMOS (Complementary Metal Oxide Semiconductor), and may be specifically manufactured in an SOI (Silicon on Insulator) process. The first semiconductor IC and the second semiconductor IC may be formed from at least one of GaAs, SiGe, and GaN. The semiconductor material of the first semiconductor IC and the second semiconductor IC is not limited to the material described above.

The output end of the amplifier 11 is connected to the common terminal 21a through a wiring line 101, a wiring line 151, the matching circuit 51, a wiring line 153, and a wiring line 103. The wiring line 101, the wiring line 151, the wiring line 153, and the wiring line 103 are defined collectively as first wiring.

The output end of the amplifier 12 is connected to the common terminal 22a through a wiring line 102, a wiring line 152, the matching circuit 52, a wiring line 154, and a wiring line 104. The wiring line 102, the wiring line 152, the wiring line 154, and the wiring line 104 are defined collectively as second wiring.

The wiring lines 151, 152, 153, and 154 are formed on the first principal surface of the module substrate 90 or in the module substrate 90. The wiring lines 101 and 102 are formed in the first semiconductor IC which includes the power amplifier circuit 10. The wiring lines 103 and 104 are formed in the second semiconductor IC which includes the switch circuit 20.

The first wiring and the second wiring are desirably disposed adjacent to each other. This suppresses power leakage and spurious leakage which are caused by imbalance between a pair of balanced signals transmitted through the first wiring and the second wiring.

Further, the first wiring and the second wiring desirably have the same wiring line length. This further suppresses power leakage and spurious leakage which are caused by imbalance between a pair of balanced signals transmitted through the first wiring and the second wiring.

The first wiring and the second wiring do not necessarily have the same wiring line length in a strict sense. The total of the wiring line lengths of the wiring lines 151 and 153 in the first wiring may be the same as that of the wiring lines 152 and 154 in the second wiring. This suppresses power leakage and spurious leakage from the wiring lines formed in or on the module substrate 90.

The balanced terminal 31a of the filter 31 is connected to the selection terminal 21b of the switch circuit 20 through a wiring line 134 (third wiring); the balanced terminal 31b, to the selection terminal 22b through a wiring line 135 (fourth wiring). The balanced terminal 32a of the filter 32 is connected to the selection terminal 21c through a wiring line 136 (third wiring); the balanced terminal 32b, to the selection terminal 22c through a wiring line 137 (fourth wiring). The balanced terminal 33a of the filter 33 is connected to the selection terminal 21d through a wiring line 138 (third wiring); the balanced terminal 33b, to the selection terminal 22d through a wiring line 139 (fourth wiring).

The switch 40 is connected to the filter 31 through a wiring line 131; to the filter 32, through a wiring line 132; to the filter 33, through a wiring line 133.

The wiring lines 131, 132, 133, 134, 135, 136, 137, 138, and 139 are formed on the first principal surface of the module substrate 90 or in the module substrate 90.

Desirably, the wiring line 134 and the wiring line 135 are disposed adjacent to each other; the wiring line 136 and the wiring line 137 are disposed adjacent to each other; the wiring line 138 and the wiring line 139 are disposed adjacent to each other. This suppresses power leakage and spurious leakage which are caused by imbalance between a pair of balanced signals transmitted through the third wiring and the fourth wiring.

Desirably, the wiring line 134 and the wiring line 135 have the same wiring line length; the wiring line 136 and the wiring line 137 have the same wiring line length; the wiring line 138 and the wiring line 139 have the same wiring line length. This further suppresses power leakage and spurious leakage which are caused by imbalance between a pair of balanced signals transmitted through the first wiring and the second wiring.

### [2. Effects and the Like]

The radio frequency module 1 according to the present embodiment includes the amplifiers 11 and 12 which form an amplifier circuit of differential amplification type, the switch 21 which has the common terminal 21a and the selection terminals 21b and 21c, the switch 22 which has the common terminal 22a and the selection terminals 22b and 22c, and the filter 31 which has the balanced terminals 31a and 31b and the unbalanced terminal 31c and which has a passband including the first band, and the filter 32 which has the balanced terminals 32a and 32b and the unbalanced terminal 32c and which has a passband including the second band. The common terminal 21a is connected to the output end of the amplifier 11. The common terminal 22a is connected to the output end of the amplifier 12. The selection terminal 21b is connected to the balanced terminal 31a. The selection terminal 21c is connected to the balanced terminal 32a. The selection terminal 22b is connected to the balanced terminal 31b. The selection terminal 22c is connected to the balanced terminal 32b.

According to this, balanced signals are transmitted through all the signal paths from the amplifiers 11 and 12 to the filters 31 to 33. Thus, compared with a circuit in which unbalanced signals are transmitted through the signal paths, the power of a signal transmitted through each signal path may be reduced, achieving low power consumption. In addition, the reduction of the signal power allows a reduction of the electric power handling capability of the switches 21 and 22 and the filters 31 to 33 and a reduction in size of the switches 21 and 22 and the filters 31 to 33. Therefore, the radio frequency module 1 which allows low power consumption and a reduction in size may be provided.

In addition, for example, in the radio frequency module 1, the switch 21 may switch between connection between the common terminal 21a and the selection terminal 21b and connection between the common terminal 21a and the selection terminal 21c; the switch 22 may switch between connection between the common terminal 22a and the selection terminal 22b and connection between the common terminal 22a and the selection terminal 22c. Assuming the common terminal 21a is connected to the selection terminal 21b, the common terminal 22a may be connected to the selection terminal 22b. Assuming the common terminal 21a is connected to the selection terminal 21c, the common terminal 22a may be connected to the selection terminal 22c.

According to this, in the case of transmission of a signal of the first band, the signal of the first band passes through the filter 31 due to the switching operations performed by the switches 21 and 22. In the case of transmission of a signal of the second band, the signal of the second band passes through the filter 32 due to the switching operations performed by the switches 21 and 22.

In addition, for example, in the radio frequency module 1, each of the switches 21 and 22 may include multiple semiconductor devices. The stacks of the one or more semiconductor devices serially connected between the common terminal 21a and the selection terminal 21b may be equal in number to the stacks of the one or more semiconductor devices connected between the common terminal 22a and the selection terminal 22b. The stacks of the one or more semiconductor devices connected between the common terminal 21a and the selection terminal 21c may be equal in number to those between the common terminal 22a and the selection terminal 22c.

According to this, the on-resistance of the path connecting the common terminal 21a to the selection terminal 21b is equal to that of the path connecting the common terminal 22a to the selection terminal 22b. A balanced signal flowing through the path connecting the common terminal 21a to the selection terminal 21b and a balanced signal flowing through the path connecting the common terminal 22a to the selection terminal 22b are received at the balanced terminals 31a and 31b, respectively, of the filter 31 at the same time. This enables the degree of balance between a pair of balanced signals, which pass through the filter 31, to be improved. In addition, the on-resistance of the path connecting the common terminal 21a to the selection terminal 21c is equal to that of the path connecting the common terminal 22a to the selection terminal 22c. A balanced signal flowing through the path connecting the common terminal 21a to the selection terminal 21c and a balanced signal flowing through the path connecting the common terminal 22a to the selection terminal 22c are received at the balanced terminals 32a and 32b, respectively, of the filter 32 at the same time. This enables the degree of balance between a pair of balanced signals, which pass through the filter 32, to be improved.

In addition, for example, the radio frequency module 1 may further include the signal input terminal 110 and the transformer 15 having a primary coil and a secondary coil. The primary coil may be connected, at its first end, to the signal input terminal 110. The primary coil may be grounded at its second end. The secondary coil may be connected, at its first end, to the input end of the amplifier 11. The secondary coil may be connected, at its second end, to the input end of the amplifier 12.

In addition, for example, in the radio frequency module 1, the amplifiers 11 and 12 may be formed in the first semiconductor IC. The transformer 15 may be included in the first semiconductor IC.

This achieves a reduction in size of the radio frequency module 1.

In addition, for example, the radio frequency module 1 may further include the antenna connection terminal 100 and the switch 40 which is connected between the antenna connection terminal 100 and the filters 31 and 32.

In addition, for example, in the radio frequency module 1, a transformer is not necessarily connected between the output ends of the amplifiers 11 and 12 and the input ends of the filters 31 and 32.

According to this, a transformer which converts balanced signals to unbalanced signals is not disposed on the signal paths from the amplifiers 11 and 12 to the filters 31 and 32, achieving a further reduction in size of the radio frequency module 1.

In addition, for example, the radio frequency module 1A according to the modified example may include multiple first amplifiers (the amplifiers 111, 112, and 11m), multiple second amplifiers (the amplifiers 121, 122, and 12m), multiple first switches, multiple second switches, multiple first filters (the filters 311, 312, and 31m), and multiple second filters (the filters 321, 322, and 32m). The first amplifiers may be connected, at their input ends, to each other. The second amplifiers may be connected, at their input ends, to each other. The first common terminal of a first one of the first switches may be connected to the output end of a first one of the first amplifiers. The first common terminal of a second one of the first switches may be connected to the output end of a second one of the first amplifiers. The second common terminal of a first one of the second switches may be connected to the output end of a first one of the second amplifiers. The second common terminal of a second one of the second switches may be connected to the output end of a second one of the second amplifiers. The first selection terminal of the first one of the first switches may be connected to the first balanced terminal of a first one of the first filters. The second selection terminal of the first one of the first switches may be connected to the third balanced terminal of a first one of the second filters. The first selection terminal of the second one of the first switches may be connected to the first balanced terminal of a second one of the first filters. The second selection terminal of the second one of the first switches may be connected to the third balanced terminal of a second one of the second filters. The third selection terminal of the first one of the second switches may be connected to the second balanced terminal of the first one of the first filters. The fourth selection terminal of the first one of the second switches may be connected to the fourth balanced terminal of the first one of the second filters. The third selection terminal of the second one of the second switches may be connected to the second balanced terminal of the second one of the first filters. The fourth selection terminal of the second one of the second switches may be connected to the fourth balanced terminal of the second one of the second filters. The first filters may be connected, at their first unbalanced terminals, to each other. The second filters may be connected, at their second unbalanced terminals, to each other.

According to this, balanced signals are transmitted through all the signal paths from the output ends of the first amplifiers and the second amplifiers to the first filters and the second filters. Thus, compared with a circuit in which unbalanced signals are transmitted through the signal paths, the power of a signal transmitted through each signal path may be reduced, achieving low power consumption. The reduction of the signal power allows a reduction of electric power handling capability of the first switches, the second switches, the first filters, and the second filters, achieving a reduction in size of these components. Therefore, the radio frequency module 1A which allows low power consumption and a reduction in size may be provided.

In addition, for example, the radio frequency module 1 may further include the module substrate 90 including the amplifiers 11 and 12, the switches 21 and 22, and the filters 31 and 32. The first wiring connecting the output end of the amplifier 11 to the common terminal 21a may be disposed adjacent to the second wiring connecting the output end of the amplifier 12 to the common terminal 22a.

This suppresses power leakage and spurious leakage which are caused by imbalance between a pair of balanced signals transmitted through the first wiring and the second wiring.

In addition, for example, in the radio frequency module 1, the first wiring and the second wiring may have the same wiring line length.

This further suppresses power leakage and spurious leakage which are caused by imbalance between a pair of balanced signals transmitted through the first wiring and the second wiring.

In addition, for example, in the radio frequency module 1, the third wiring connecting the selection terminal 21b to the balanced terminal 31a may be disposed adjacent to the fourth wiring connecting the selection terminal 22b to the balanced terminal 31b.

This suppresses power leakage and spurious leakage which are caused by imbalance between a pair of balanced signals transmitted through the third wiring and the fourth wiring.

In addition, for example, in the radio frequency module 1, the third wiring and the fourth wiring may have the same wiring line length.

This further suppresses power leakage and spurious leakage which are caused by imbalance between a pair of balanced signals transmitted through the third wiring and the fourth wiring.

In addition, for example, in the radio frequency module 1, the amplifiers 11 and 12 may be included in the first semiconductor IC disposed on the module substrate 90. The switches 21 and 22 may be included in the second semiconductor IC disposed on the module substrate 90. Each of the filters 31 and 32 may be disposed on the module substrate 90.

This achieves a reduction in size of the radio frequency module 1.

In addition, the communication device 4 according to the present embodiment includes the RFIC 3 that processes a radio frequency signal, and the radio frequency module 1 that transmits the radio frequency signal between the RFIC 3 and the antenna 2.

This enables the effects of the radio frequency module 1 to be exerted in the communication device 4.

### Other Embodiments and the Like

The radio frequency module and the communication device according to the embodiment are described above by taking the embodiment and the modified example. However, the radio frequency module and the communication device according to the present disclosure are not limited to the embodiment and the modified example. The present disclosure also encompasses another embodiment obtained by combining any components in the embodiment and the modified example with each other, a modified example obtained by making, on the embodiment and the modified example, various modifications conceived by those skilled in the art without departing from the gist of the present disclosure, and various devices in which the radio frequency module and the communication device are included.

For example, in the radio frequency module and the communication device according to the embodiment and the modified example, different circuit devices, wiring lines, and the like may be inserted among paths connecting the circuit devices and the signal paths which are disclosed in the drawings.

The features of the radio frequency module and the communication device, which are described on the basis of the embodiment and the modified example, are described below.

<1>

A radio frequency module comprising:
a first amplifier and a second amplifier that form an amplifier circuit of differential amplification type;
a first switch that has a first common terminal, a first selection terminal, and a second selection terminal;
a second switch that has a second common terminal, a third selection terminal, and a fourth selection terminal;
a first filter that has a first balanced terminal, a second balanced terminal, and a first unbalanced terminal and that has a passband including a first band; and
a second filter that has a third balanced terminal, a fourth balanced terminal, and a second unbalanced terminal and that has a passband including a second band,
wherein the first common terminal is connected to an output end of the first amplifier,
wherein the second common terminal is connected to an output end of the second amplifier,
wherein the first selection terminal is connected to the first balanced terminal,
wherein the second selection terminal is connected to the third balanced terminal,
wherein the third selection terminal is connected to the second balanced terminal, and
wherein the fourth selection terminal is connected to the fourth balanced terminal.

<2>

The radio frequency module according to <1>,
wherein the first switch switches between connection between the first common terminal and the first selection terminal and connection between the first common terminal and the second selection terminal,
wherein the second switch switches between connection between the second common terminal and the third selection terminal and connection between the second common terminal and the fourth selection terminal,
wherein connection between the first common terminal and the first selection terminal and connection between the second common terminal and the third selection terminal are established at the same time, and
wherein connection between the first common terminal and the second selection terminal and connection between the second common terminal and the fourth selection terminal are established at the same time.

<3>

The radio frequency module according to <1> or <2>,
wherein each of the first switch and the second switch includes a plurality of semiconductor devices,
wherein stacks of one or more semiconductor devices serially connected between the first common terminal and the first selection terminal are equal, in number, to stacks of one or more semiconductor devices connected between the second common terminal and the third selection terminal, and
wherein stacks of one or more semiconductor devices connected between the first common terminal and the second selection terminal is equal, in number, to stacks of one or more semiconductor devices connected between the second common terminal and the fourth selection terminal.

<4>

The radio frequency module according to any one of <1> to <3>, further comprising:
a signal input terminal; and
a transformer that has a primary coil and a secondary coil,
wherein the primary coil is connected, at a first end thereof, to the signal input terminal,
wherein the primary coil is grounded at a second end thereof,
wherein the secondary coil is connected, at a first end thereof, to an input end of the first amplifier, and
wherein the secondary coil is connected, at a second end thereof, to an input end of the second amplifier.

<5>

The radio frequency module according to <4>,
wherein the first amplifier and the second amplifier are formed in a first semiconductor IC, and
wherein the transformer is included in the first semiconductor IC.

<6>

The radio frequency module according to any one of <1> to <5>, further comprising:
an antenna connection terminal; and
a third switch that is connected between the antenna connection terminal and the first and second filters.

<7>

The radio frequency module according to any one of <1> to <6>,
wherein a transformer is not connected between the output ends of the first and second amplifiers and input ends of the first and second filters.

<8>

The radio frequency module according to any one of <1> to <7>, comprising:
a plurality of the first amplifiers;
a plurality of the second amplifiers;
a plurality of the first switches;
a plurality of the second switches;
a plurality of the first filters; and
a plurality of the second filters,
wherein the plurality of the first amplifiers are connected, at input ends thereof, to each other,
wherein the plurality of the second amplifiers are connected, at input ends thereof, to each other,
wherein the first common terminal of a first one of the plurality of the first switches is connected to the output end of a first one of the plurality of the first amplifiers,
wherein the first common terminal of a second one of the plurality of the first switches is connected to the output end of a second one of the plurality of the first amplifiers,
wherein the second common terminal of a first one of the plurality of the second switches is connected to the output end of a first one of the plurality of the second amplifiers,
wherein the second common terminal of a second one of the plurality of the second switches is connected to the output end of a second one of the plurality of the second amplifiers,
wherein the first selection terminal of the first one of the plurality of the first switches is connected to the first balanced terminal of a first one of the plurality of the first filters,
wherein the second selection terminal of the first one of the plurality of the first switches is connected to the third balanced terminal of a first one of the plurality of the second filters,
wherein the first selection terminal of the second one of the plurality of the first switches is connected to the first balanced terminal of a second one of the plurality of the first filters,
wherein the second selection terminal of the second one of the plurality of the first switches is connected to the third balanced terminal of a second one of the plurality of the second filters,
wherein the third selection terminal of the first one of the plurality of the second switches is connected to the second balanced terminal of the first one of the plurality of the first filters,
wherein the fourth selection terminal of the first one of the plurality of the second switches is connected to the fourth balanced terminal of the first one of the plurality of the second filters,
wherein the third selection terminal of the second one of the plurality of the second switches is connected to the second balanced terminal of the second one of the plurality of the first filters,
wherein the fourth selection terminal of the second one of the plurality of the second switches is connected to the fourth balanced terminal of the second one of the plurality of the second filters,
wherein the plurality of the first filters are connected, at the first unbalanced terminals thereof, to each other, and
wherein the plurality of the second filters are connected, at the second unbalanced terminals thereof, to each other.

<9>

The radio frequency module according to any one of <1> to <8>, further comprising:
a module substrate that includes the first amplifier, the second amplifier, the first switch, the second switch, the first filter, and the second filter,
wherein first wiring connecting the output end of the first amplifier to the first common terminal is disposed adjacent to second wiring connecting the output end of the second amplifier to the second common terminal.

<10>

The radio frequency module according to <9>,
wherein the first wiring and the second wiring have an identical wiring line length.

<11>

The radio frequency module according to <9> or <10>,
wherein third wiring connecting the first selection terminal to the first balanced terminal is disposed adjacent to fourth wiring connecting the third selection terminal to the second balanced terminal.

<12>

The radio frequency module according to <11>,
wherein the third wiring and the fourth wiring have an identical wiring line length.

<13>

The radio frequency module according to any one of <9> to <12>,
wherein the first amplifier and the second amplifier are included in a first semiconductor IC disposed on the module substrate,
wherein the first switch and the second switch are included in a second semiconductor IC disposed on the module substrate, and
wherein each of the first filter and the second filter is disposed on the module substrate.

<14>

A communication device comprising:
a signal processing circuit that processes a radio frequency signal; and
the radio frequency module according to any one of <1> to <13> that transmits the radio frequency signal between the signal processing circuit and an antenna.

### INDUSTRIAL APPLICABILITY

The present disclosure may be used widely in communication devices such as a cellular phone, as a radio frequency module disposed in a multiband-capable front-end unit.

### REFERENCE SIGNS LIST

1, 1A, 500 radio frequency module
2 antenna
3 RF signal processing circuit (RFIC)
4, 4A communication device
10, 10A power amplifier circuit
11, 12, 13, 111, 112, 11m, 121, 122, 12m amplifier
15, 540 transformer
20, 20A switch circuit
21, 22, 24, 40 switch
21a, 22a, 24a, 251, 252, 25m, 261, 262, 26m common terminal
21b, 21c, 21d, 22b, 22c, 22d, 24b, 24c, 24d, 271n, 271p, 272n, 272p, 27mn, 27mp, 281n, 281p, 282n, 282p, 28mn, 28mp, 291n, 291p, 292n, 292p, 29mn, 29mp selection terminal
31, 32, 33, 311, 312, 31m, 321, 322, 32m, 331, 332, 33m, 531, 532, 533 filter
31A, 32A, 33A filter circuit
31a, 31b, 32a, 32b, 33a, 33b balanced terminal
31c, 32c, 33c unbalanced terminal
51, 52, 56, 511, 512, 51m, 521, 522, 52m matching circuit
90 module substrate
100 antenna connection terminal
101, 102, 103, 104, 131, 132, 133, 134, 135, 136, 137, 138, 139, 151, 152, 153, 154 wiring line
110 signal input terminal
310, 320, 330, 340, 350 IDT electrode
360, 370 reflecting electrode

1. A radio frequency module comprising:
a first amplifier and a second amplifier that form an amplifier circuit of differential amplification type;
a first switch that has a first common terminal, a first selection terminal, and a second selection terminal;
a second switch that has a second common terminal, a third selection terminal, and a fourth selection terminal;
a first filter that has a first balanced terminal, a second balanced terminal, and a first unbalanced terminal and that has a passband including a first band; and
a second filter that has a third balanced terminal, a fourth balanced terminal, and a second unbalanced terminal and that has a passband including a second band,
wherein the first common terminal is connected to an output end of the first amplifier,
wherein the second common terminal is connected to an output end of the second amplifier,
wherein the first selection terminal is connected to the first balanced terminal,
wherein the second selection terminal is connected to the third balanced terminal,
wherein the third selection terminal is connected to the second balanced terminal, and
wherein the fourth selection terminal is connected to the fourth balanced terminal.

2. The radio frequency module according to claim 1,
wherein the first switch switches between connection between the first common terminal and the first selection terminal and connection between the first common terminal and the second selection terminal,
wherein the second switch switches between connection between the second common terminal and the third selection terminal and connection between the second common terminal and the fourth selection terminal,
wherein, assuming the first common terminal is connected to the first selection terminal, the second common terminal is connected to the third selection terminal, and
wherein, assuming the first common terminal is connected to the second selection terminal, the second common terminal is connected to the fourth selection terminal.

3. The radio frequency module according to claim 1,
wherein each of the first switch and the second switch includes a plurality of semiconductor devices,
wherein stacks of one or more semiconductor devices serially connected between the first common terminal and the first selection terminal are equal, in number, to stacks of one or more semiconductor devices connected between the second common terminal and the third selection terminal, and
wherein stacks of one or more semiconductor devices connected between the first common terminal and the second selection terminal is equal, in number, to stacks of one or more semiconductor devices connected between the second common terminal and the fourth selection terminal.

4. The radio frequency module according to claim 1, further comprising:
a signal input terminal; and
a transformer that has a primary coil and a secondary coil,
wherein the primary coil is connected, at a first end thereof, to the signal input terminal,
wherein the primary coil is grounded at a second end thereof,
wherein the secondary coil is connected, at a first end thereof, to an input end of the first amplifier, and
wherein the secondary coil is connected, at a second end thereof, to an input end of the second amplifier.

5. The radio frequency module according to claim 4,
wherein the first amplifier and the second amplifier are formed in a first semiconductor IC, and
wherein the transformer is included in the first semiconductor IC.

6. The radio frequency module according to claim 1, further comprising:
an antenna connection terminal; and
a third switch that is connected between the antenna connection terminal and the first and second filters.

7. The radio frequency module according to claim 1,
wherein a transformer is not connected between the output ends of the first and second amplifiers and input ends of the first and second filters.

8. The radio frequency module according to claim 1, comprising:
a plurality of the first amplifiers;
a plurality of the second amplifiers;
a plurality of the first switches;
a plurality of the second switches;
a plurality of the first filters; and
a plurality of the second filters,
wherein the plurality of the first amplifiers are connected, at input ends thereof, to each other,
wherein the plurality of the second amplifiers are connected, at input ends thereof, to each other,
wherein the first common terminal of a first one of the plurality of the first switches is connected to the output end of a first one of the plurality of the first amplifiers,
wherein the first common terminal of a second one of the plurality of the first switches is connected to the output end of a second one of the plurality of the first amplifiers,
wherein the second common terminal of a first one of the plurality of the second switches is connected to the output end of a first one of the plurality of the second amplifiers,
wherein the second common terminal of a second one of the plurality of the second switches is connected to the output end of a second one of the plurality of the second amplifiers,
wherein the first selection terminal of the first one of the plurality of the first switches is connected to the first balanced terminal of a first one of the plurality of the first filters,
wherein the second selection terminal of the first one of the plurality of the first switches is connected to the third balanced terminal of a first one of the plurality of the second filters,
wherein the first selection terminal of the second one of the plurality of the first switches is connected to the first balanced terminal of a second one of the plurality of the first filters,
wherein the second selection terminal of the second one of the plurality of the first switches is connected to the third balanced terminal of a second one of the plurality of the second filters,
wherein the third selection terminal of the first one of the plurality of the second switches is connected to the second balanced terminal of the first one of the plurality of the first filters,
wherein the fourth selection terminal of the first one of the plurality of the second switches is connected to the fourth balanced terminal of the first one of the plurality of the second filters,
wherein the third selection terminal of the second one of the plurality of the second switches is connected to the second balanced terminal of the second one of the plurality of the first filters,
wherein the fourth selection terminal of the second one of the plurality of the second switches is connected to the fourth balanced terminal of the second one of the plurality of the second filters,
wherein the plurality of the first filters are connected, at the first unbalanced terminals thereof, to each other, and
wherein the plurality of the second filters are connected, at the second unbalanced terminals thereof, to each other.

9. The radio frequency module according to claim 1, further comprising:
a module substrate that includes the first amplifier, the second amplifier, the first switch, the second switch, the first filter, and the second filter,
wherein first wiring connecting the output end of the first amplifier to the first common terminal is disposed adjacent to second wiring connecting the output end of the second amplifier to the second common terminal.

10. The radio frequency module according to claim 9,
wherein the first wiring and the second wiring have an identical wiring line length.

11. The radio frequency module according to claim 9,
wherein third wiring connecting the first selection terminal to the first balanced terminal is disposed adjacent to fourth wiring connecting the third selection terminal to the second balanced terminal.

12. The radio frequency module according to claim 11,
wherein the third wiring and the fourth wiring have an identical wiring line length.

13. The radio frequency module according to claim 9,
wherein the first amplifier and the second amplifier are included in a first semiconductor IC disposed on the module substrate,
wherein the first switch and the second switch are included in a second semiconductor IC disposed on the module substrate, and
wherein each of the first filter and the second filter is disposed on the module substrate.

14. A communication device comprising:
a signal processing circuit that processes a radio frequency signal; and
the radio frequency module according to claim 1 that transmits the radio frequency signal between the signal processing circuit and an antenna.

15. A communication device comprising:
a signal processing circuit that processes a radio frequency signal; and
the radio frequency module according to claim 2 that transmits the radio frequency signal between the signal processing circuit and an antenna.

16. A communication device comprising:
a signal processing circuit that processes a radio frequency signal; and
the radio frequency module according to claim 3 that transmits the radio frequency signal between the signal processing circuit and an antenna.

17. A communication device comprising:
a signal processing circuit that processes a radio frequency signal; and
the radio frequency module according to claim 4 that transmits the radio frequency signal between the signal processing circuit and an antenna.

18. A communication device comprising:
a signal processing circuit that processes a radio frequency signal; and
the radio frequency module according to claim 5 that transmits the radio frequency signal between the signal processing circuit and an antenna.

19. A communication device comprising:
a signal processing circuit that processes a radio frequency signal; and
the radio frequency module according to claim 6 that transmits the radio frequency signal between the signal processing circuit and an antenna.

20. A communication device comprising:
a signal processing circuit that processes a radio frequency signal; and
the radio frequency module according to claim 7 that transmits the radio frequency signal between the signal processing circuit and an antenna.
